(19) United States
(12) Patent Application Publication
(10) Pub. No.: US 2014/0332056 A1
(43) Pub. Date: Nov. 13, 2014

(54) DEVICE FOR GENERATING ELECTRIC POWER AND ABSORBING HEAT

(71) Applicant: SOUTHERN TAIWAN UNIVERSITY OF SCIENCE AND TECHNOLOGY, Tainan City (TW)

(72) Inventors: RUEI-TANG CHEN, TAINAN CITY (TW); JHIH-WUN LAI, TAINAN CITY (TW); RU-SYUAN WU, TAINAN CITY (TW); JYUN-FU SHIH, TAINAN CITY (TW)

(73) Assignee: SOUTHERN TAIWAN UNIVERSITY OF SCIENCE AND TECHNOLOGY, Tainan City (TW)

(21) Appl. No.: 14/272,783

(22) Filed: May 8, 2014

(30) Foreign Application Priority Data
May 13, 2013 (TW) 102116943

(51) Int. Cl. H01L 31/0525

(52) U.S. Cl. CPC H01L 31/058; Y10S 977/948; Y10S 977/742; Y10S 977/755
USPC 136/248; 136/246; 977/948; 977/742; 977/755

(57) ABSTRACT

A device for generating electric power and absorbing heat is revealed. It comprises a substrate, a plurality of solar chips, a broad spectrum light absorbing layer and a light scattering film on the substrate and beside the solar chips, a hot melt adhesive film, and a transparent cover plate.

### BACKGROUND OF THE INVENTION

1. Field of the Invention

The present invention relates to a device for generating electric power and absorbing heat. It can be utilized in a solar water heater by providing a broad spectrum light absorbing layer for absorbing visible and invisible light and providing a light scattering film for scattering short-wavelength light, so as to increase heat absorption and enhance generation of electric power.

2. Description of Related Art

Solar technologies are broadly characterized as either passive solar or active solar. Active solar includes photovoltaic panels and photo-thermal conversion, e.g. using electricity or mechanical apparatus depending on external energy for collecting solar energy, while passive solar includes orienting a building to the Sun or selecting favorable materials for collecting solar energy without depending on external energy.

Currently on the market, most solar water heaters merely have heating function. For instance, a Taiwan Patent No. M446314, issued on 1 Feb. 2013, has disclosed a solar water heater having thin film solar cell, comprising a frame, a water storage tank, a top plate, a thin film solar cell, a collector unit, and a water circulation channel, wherein the top plate, the thin film solar cell and the collector unit were disposed from top to bottom in the frame, the water circulation channel is disposed below the thin film solar cell in the frame and communicates with the water storage tank, and the top plate is a flat plate-like structure having a light transmissible material. However, the aforementioned structure is unable to simultaneously absorb heat and generate electric power.

In addition, although some solar power generation modules are equipped with power generation and water heating function, they usually cannot effectively heat the water to the desired temperature. Furthermore, some solar water heaters are provided with a heat conduction device coupled with a thermoelectric energy conversion module to generate electric power. For instance, a Taiwan Patent No. M443148, issued on 11 Dec. 2012, has disclosed a solar water heater having power generation function, comprising a heat storage barrel, a collector device, and a CIGS thin film solar power module having a CIGS thin film solar panel, an electricity storage unit, and a control unit, wherein the CIGS thin film solar panel is disposed on a heat collector pipe of the collector device and electrically connects the electricity storage unit, the electricity storage unit electrically connects the control unit, and the control unit electrically connects a heating device of the heat storage barrel. Accordingly, electric power stored in the collector device allows the heating device to heat water stored in the heat storage barrel at night or when the sunshine is insufficient, so that operation of the solar water heaters are not limited by intensity of sunshine.

However, thermoelectric chip technology is still not good enough to effectively generate sufficient electric power, especially in the environment with small temperature difference. In consideration of the limited area of roof and other economic factors, people cannot but choose only one of the aforementioned solar water heaters to install. Therefore, some disadvantages are existed in the installed solar water heaters, i.e. unable to have both functions of heat absorption and electric power generation as well as unable to absorb solar energy completely.

### SUMMARY OF THE INVENTION

In view of the above-mentioned problems, the object of the present invention is to provide a device for generating electric power and absorbing heat. It can be utilized in a solar water heater by providing a broad spectrum light absorbing layer for increasing light absorption and a light scattering film for scattering light, so as to increase heat absorption and enhance generation of electric power.

Disclosed herein is a device for generating electric power and absorbing heat, comprising a substrate, a plurality of solar chips, a broad spectrum light absorbing layer and a light scattering film on the substrate and beside the solar chips, a hot melt adhesive film, and a transparent cover plate, wherein the broad spectrum light absorbing layer absorbs visible and invisible light (i.e. ultraviolet light and infrared light) to increase heat absorption and the light scattering film scatters short-wavelength light to the plurality of solar chip for enhancing generation of electric power.

According to an embodiment of the present invention, the light absorbing material of the broad spectrum light absorbing layer is selected from carbon nanocapsule, carbon nanotube, grapheme, or carbon black.

According to an embodiment of the present invention, the broad spectrum light absorbing layer comprises a hot melt adhesive and a light absorbing material, wherein the light absorbing material is dispersed in the hot melt adhesive.

According to an embodiment of the present invention, the light scattering film is made from a hot melt adhesive added with scattering particles having a diameter between 5 to 400 nanometers.

According to an embodiment of the present invention, the device for generating electric power and absorbing heat is utilized in a solar water heater to raise the temperature of water flowing through therein.

According to an embodiment of the present invention, the device for generating electric power and absorbing heat can be combined with an electric accumulator or disposed in parallel with supply mains.

### BRIEF DESCRIPTION OF THE DRAWINGS

FIG. 1 is a cross-sectional diagram showing a device for generating electric power and absorbing heat according to the present invention;

FIG. 2 is a schematic diagram showing a device for generating electric power and absorbing heat according to the present invention;

FIG. 3 is a schematic diagram showing a device for generating electric power and absorbing heat utilized in a solar water heater;

FIG. 4 is a diagram showing an absorption spectrum of a light absorbing material using carbon nanocapsule;

FIG. 5 is a diagram showing a reflection spectrum of a light scattering film.

### DETAILED DESCRIPTION OF THE PREFERRED EMBODIMENT

Hereinafter, an exemplary embodiment of the present invention will be described in detail with reference to the accompanying drawings.

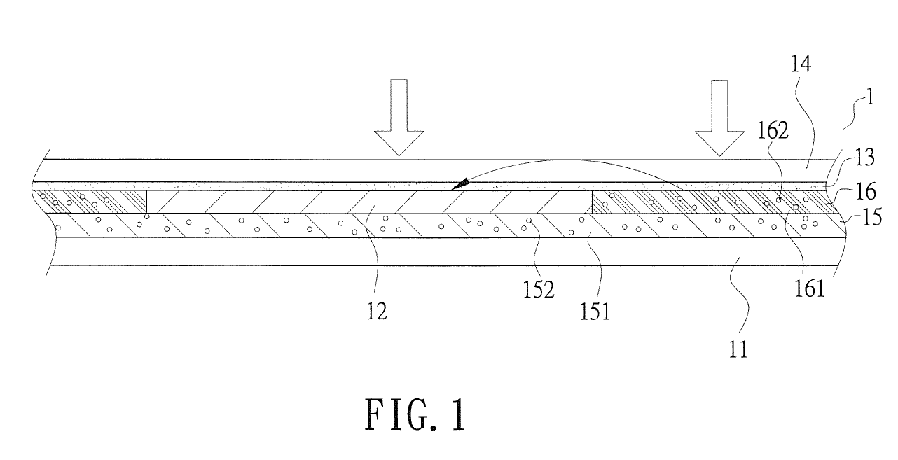

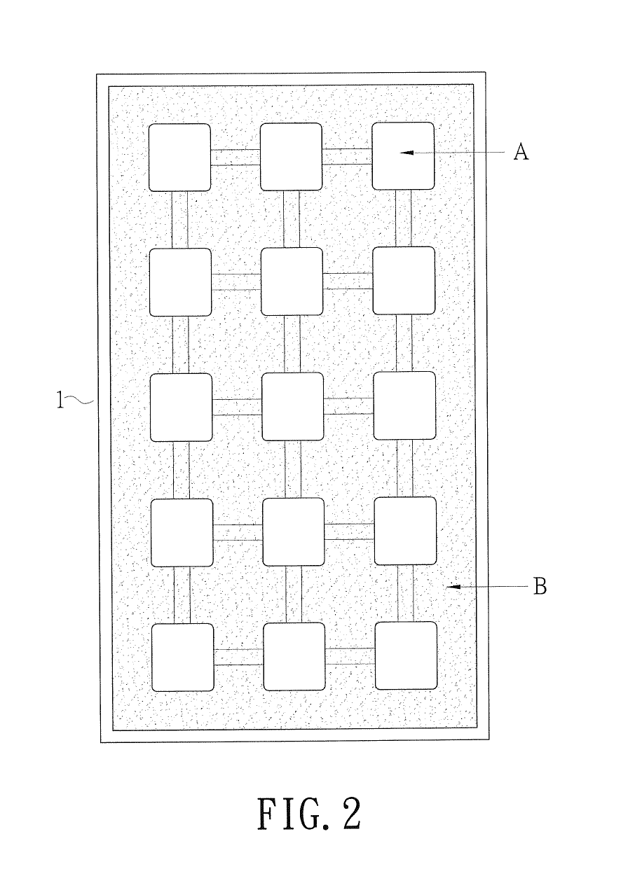

Referring to FIG. 1 and FIG. 2, a cross-sectional diagram and a schematic diagram showing a device for generating electric power and absorbing heat according to the present invention are revealed. The device for generating electric power and absorbing heat (1) comprises a substrate (11), a plurality of solar chips (12), a hot melt adhesive film (13) and a transparent cover plate (14), wherein a broad spectrum light absorbing layer (15) and a light scattering film (16) are disposed between the substrate (11) and the hot melt adhesive film (13), the broad spectrum light absorbing layer (15) covers on the substrate (11), and the light scattering film (16) is disposed below the hot melt adhesive film (13) and beside the plurality of solar chips (12). Accordingly, the broad spectrum light absorbing layer (15) can absorb visible and invisible light (i.e. ultraviolet light and infrared light) to increase heat absorption, and the light scattering film (16) can scatter short-wavelength light to the plurality of solar chips (12) to enhance generation of electric power.

An exemplary embodiment of the present invention will be described with reference to FIG. 1 and FIG. 2. First, a substrate (11) is prepared, and a broad spectrum light absorbing layer (15) is disposed on the substrate (11). The broad spectrum light absorbing layer (15) comprises a light absorbing material (152) directly coated on the substrate (11) or comprises a hot melt adhesive (151) and a light absorbing material (152). The light absorbing material (152) is selected from carbon nanocapsule, carbon nanotube, grapheme, or carbon black and is dispersed in the hot melt adhesive (151). Then a light scattering film (16) which is made from a hot melt adhesive (161) added with scattering particles (162) is disposed on the broad spectrum light absorbing layer (15), and the scattering particle (162) has a diameter between 5 to 400 nanometers. Moreover, a plurality of solar chips (12) is sequentially disposed on the broad spectrum light absorbing layer (15). A hot melt adhesive film (13) is disposed on the plural solar chips (12) and the light scattering film (16), and a transparent cover plate (14) is further disposed on the hot melt adhesive film (13) for covering and packaging by packaging technologies. After completion of the package, the device for generating electric power and absorbing heat (1) is equipped with power generation regions (A) sheltered by the plural solar chips (12) and light (heat) absorbing regions (B). Accordingly, the broad spectrum light absorbing layer (15) in the light (heat) absorbing region (B) can absorb visible and invisible light to increase heat absorption, and the scattering particles (162) of the light scattering film (16) scatters short-wavelength light to the plural solar chips (12) in the power generation region (A) for enhancing generation of electric power.

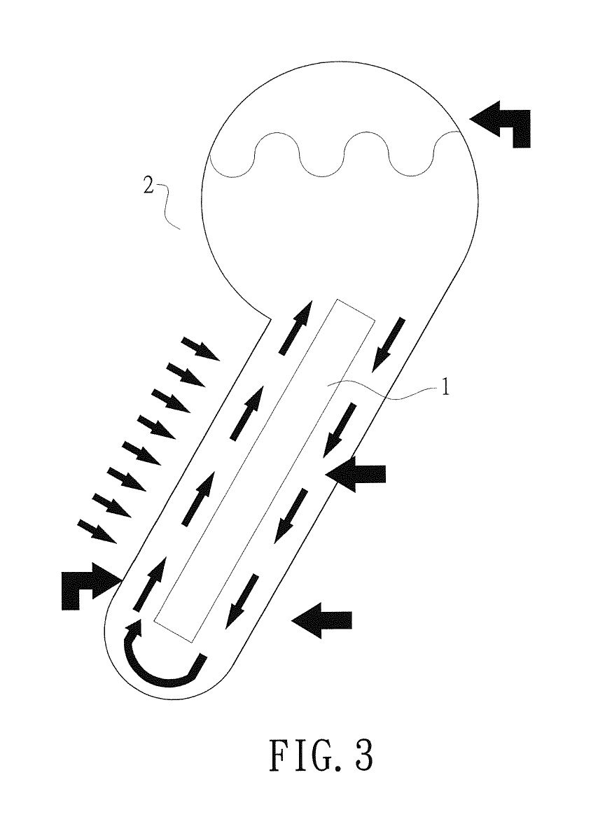

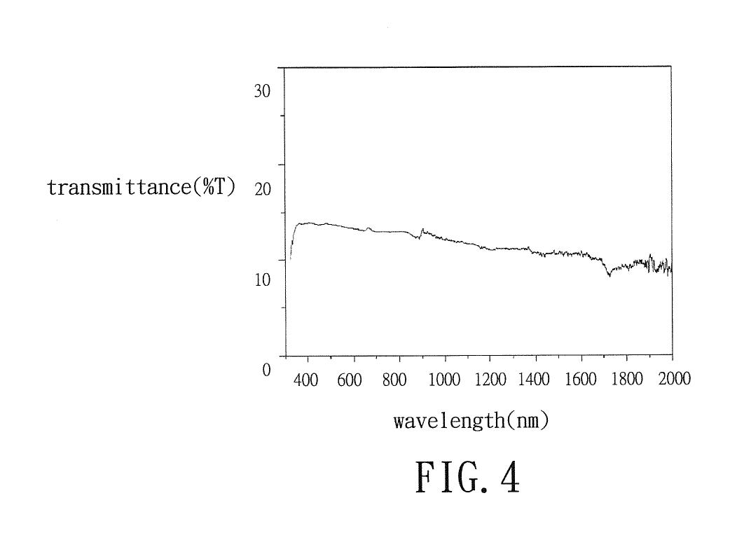

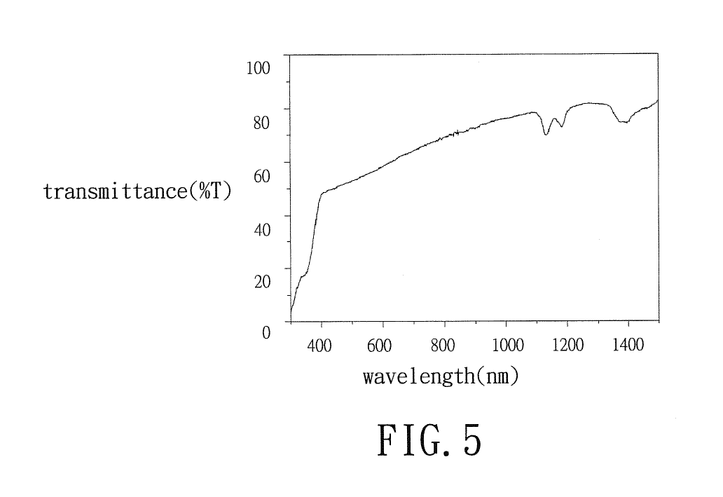

Referring to FIG. 3, the aforementioned device for generating electric power and absorbing heat (1) can be utilized in a solar water heater (2) as an absorber plate for absorbing sunlight. A diagram showing an absorption spectrum of a light absorbing material using carbon nanocapsule is revealed in FIG. 4. The carbon nanocapsule can absorb invisible light having a wavelength greater than or equal to 900 nm, and the maximum wavelength it absorbs is 2000 nm. A diagram showing a reflection spectrum of a light scattering film is revealed in FIG. 5. The scattering particles (162) can effectively reflect light having a short wavelength between 0-400 nm to the power generation region (A) for enhancing generation of electric power.

According to the aforementioned structure, the present invention combining a broad spectrum light absorbing layer (15) with a plurality of solar chips (12) in a solar water heater (2) can effectively absorb much visible and invisible light than the traditional solar panels which only absorb the maximum wavelength of 900 nm. Moreover, the broad spectrum light absorbing layer (15) absorbing visible and invisible light (i.e. ultraviolet light and infrared light) and the light scattering film (16) scattering short-wavelength visible light to the plural solar chips (12) result in enhancing generation of electric power. Therefore, when utilized in a solar water heater (2), the device for generating electric power and absorbing heat (1) can raise the temperature of water flowing through the solar water heater (2) by enhancing heat absorption and electric power generation, and the broad spectrum light absorbing layer (15) can effectively use the limited area of roof by its increased ability of light absorption.

Furthermore, the device for generating electric power and absorbing heat (1) can connect to an electric accumulator or dispose in parallel with supply mains to store electric power or sell the stored electric power, so as to achieve effect of saving electricity costs.

According to the above description, in comparison with the traditional technique, a device for generating electric power and absorbing heat according to the present invention has the advantages as following:
1. The present invention combines a broad spectrum light absorbing layer with a plurality of solar chips to effectively enhance heat absorption as well as electric power generation, and effectively use the limited area of roof by an increased ability of light absorption.
2. The present invention combining both functions of heating and electric power generation is not only eco-friendly but also energy saving. The stored electric power can further provide for use of home appliances, such as tablet computers, mobile phones, MP3, and the like.

What is claimed is:

1. A device for generating electric power and absorbing heat, comprising:
a substrate;
a broad spectrum light absorbing layer disposed on the substrate for absorbing visible and invisible light to increase heat absorption;
a plurality of solar chips disposed on the broad spectrum light absorbing layer;
a light scattering film disposed on the broad spectrum light absorbing layer and beside the plurality of solar chips to scatter short-wavelength light to the plurality of solar chips for enhancing generation of electric power;
a hot melt adhesive film disposed on the plurality of solar chips and the light scattering film; and
a transparent cover plate disposed on the hot melt adhesive film for covering and packaging the plurality of solar chips.

2. The device for generating electric power and absorbing heat as claimed in claim 1, wherein the broad spectrum light absorbing layer comprises a light absorbing material directly coated on the substrate.

3. The device for generating electric power and absorbing heat as claimed in claim 1, wherein the broad spectrum light absorbing layer comprises a hot melt adhesive and a light absorbing material dispersed in the hot melt adhesive.

4. The device for generating electric power and absorbing heat as claimed in claim 1, wherein the light scattering film is made from a hot melt adhesive added with scattering particles.

5. The device for generating electric power and absorbing heat as claimed in claim 1, wherein the device for generating electric power and absorbing heat is utilized in a solar water heater for absorbing sunlight.

6. The device for generating electric power and absorbing heat as claimed in claim 2, wherein the light absorbing material of the broad spectrum light absorbing layer is selected from carbon nanocapsule, carbon nanotube, grapheme, or carbon black.

7. The device for generating electric power and absorbing heat as claimed in claim 3, wherein the light absorbing material of the broad spectrum light absorbing layer is selected from carbon nanocapsule, carbon nanotube, grapheme, or carbon black.

8. The device for generating electric power and absorbing heat as claimed in claim 4, wherein the scattering particle has a diameter between 5 to 400 nanometers.

9. The device for generating electric power and absorbing heat as claimed in claim 5, wherein the device for generating electric power and absorbing heat raises the temperature of water flowing through the solar water heater.

10. The device for generating electric power and absorbing heat as claimed in claim 9, wherein the device for generating electric power and absorbing heat connects to an electric accumulator for storing electric power.

11. The device for generating electric power and absorbing heat as claimed in claim 9, wherein the device for generating electric power and absorbing heat is disposed in parallel with supply mains.
